(19) United States
(12) Patent Application Publication
(10) Pub. No.: US 2014/0126159 A1
(43) Pub. Date: May 8, 2014

(54) ELECTRONIC DEVICE, SYSTEM PACKAGE MODULE AND METHOD OF MANUFACTURING SYSTEM PACKAGE MODULE

(71) Applicants: UNIVERSAL SCIENTIFIC INDUSTRIAL (SHANGHAI) CO., LTD., Shanghai (CN); UNIVERSAL GLOBAL SCIENTIFIC INDUSTRIAL CO., LTD., Nantou County (TW)

(72) Inventors: YEN-HUNG LIN, CHANGHUA COUNTY (TW); TSUNG-JUNG CHENG, NANTOU COUNTY (TW)

(73) Assignees: UNIVERSAL GLOBAL SCIENTIFIC INDUSTRIAL CO., LTD., Nantou County (TW); UNIVERSAL SCIENTIFIC INDUSTRIAL (SHANGHAI) CO., LTD., SHANGHAI (CN)

(21) Appl. No.: 13/792,869

(22) Filed: Mar. 11, 2013

(30) Foreign Application Priority Data
Nov. 7, 2012 (TW) 101141299

(51) Int. Cl. H05K 1/14; H05K 3/32

(52) U.S. Cl. CPC H05K 1/14; H05K 3/32
USPC 361/736; 29/832

(57) ABSTRACT

A system in package (SiP) module includes a first circuit board assembly, a second circuit board assembly and a plurality of metallic pillars. The first circuit board assembly has a first top surface, a first bottom surface and a plurality of pads mounted on the first bottom surface. The second circuit board assembly has a second top surface, a second bottom surface and a plurality of second pads mounted on the second top surface. The metallic pillars are disposed between the first bottom surface and the second top surface. The metallic pillars electrically connect the first pad and the second pad.

### BACKGROUND

1. Field of the Invention

The instant disclosure relates to an electronic component assembly, a method of manufacturing the same and an electronic device using the electronic component assembly; in particular, to a System in Package module (SiP module), a method of manufacturing the same and an electronic device using the same.

2. Description of Related Art

A current mobile device, such as a cell phone, a tablet and a laptop, has one or more SiP modules embedded. The SiP module serves the job of data storage, graphics processing or wireless communication.

Most mobile device is capable of connecting to Internet, performing data processing and capturing images. The volume of the mobile device is ever reducing especially the thickness. Thus, a smaller volume SiP module is in great need to fit into the mobile device with smaller volume.

### SUMMARY OF THE INVENTION

According to one exemplary embodiment of the instant disclosure, a system in package (SiP) module is provided which includes a first circuit board assembly, a second circuit board assembly and a conductive pillar. The first circuit board assembly has a first circuit board unit and a first electronic component. The first circuit board unit has a first top surface, a first bottom surface and a plurality of first pads mounted on the first bottom surface. Likewise, the second circuit board assembly has a second circuit board unit and a second electronic component. The second circuit board unit has a second top surface, a second bottom surface and a plurality of second pads mounted on the second top surface. The conductive pillar is arranged between the first bottom surface and second top surface and electrically connects to corresponding first and second pads. The conductive pillar can be a metallic pillar or micro circuit board which is formed by insulating material surrounding metallic pillars.

According to another embodiment of the instant disclosure, the object is to provide a method of manufacturing the aforementioned SiP module. The method includes the steps of: firstly providing a first circuit board assembly and a circuit panel. Then, a conductive pillar is arranged and electrically connected between the first circuit board assembly and the adjacent pad of the circuit panel. Subsequently, the circuit panel is diced to form at least one SiP module. When the conductive pillar is a metallic pillar, such as a copper pillar, electrical connections between the plurality of metallic pillars and the first circuit board assembly are fabricated simultaneously by the supplement of a holder. When the conductive pillar is a micro circuit board, the micro circuit board and the other electronic components can be collectively attached by surface-mount technology (SMT).

According to another embodiment, the instant disclosure provides an electronic device, which includes a main body including at least one electronic module, a chassis, a circuit board and at least one aforementioned SiP module or a SiP module made by the above-mentioned method. One circuit board assembly of the SiP module electrically connects to the circuit board of the main body.

In order to further understand the instant disclosure, the following embodiments are provided along with illustrations to facilitate the appreciation of the instant disclosure; however, the appended drawings are merely provided for reference and illustration, without any intention to be used for limiting the scope of the instant disclosure.

### BRIEF DESCRIPTION OF THE DRAWINGS

FIG. 1A shows a cross-sectional view of a SiP module in accordance with an embodiment of the instant disclosure.

FIG. 1B shows a top view of a second circuit board assembly in FIG. 1A.

FIG. 1C shows a bottom view of a first circuit board assembly in FIG. 1A.

FIGS. 2A to 2H are schematic views of a method of manufacturing the SiP module in FIG. 1A.

FIGS. 3A to 3F are schematic views of a method of manufacturing a SiP module in accordance with another embodiment of the instant disclosure.

FIG. 4 shows a schematic view of an electronic device in accordance with an embodiment of the instant disclosure.

### DETAILED DESCRIPTION OF THE PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings.

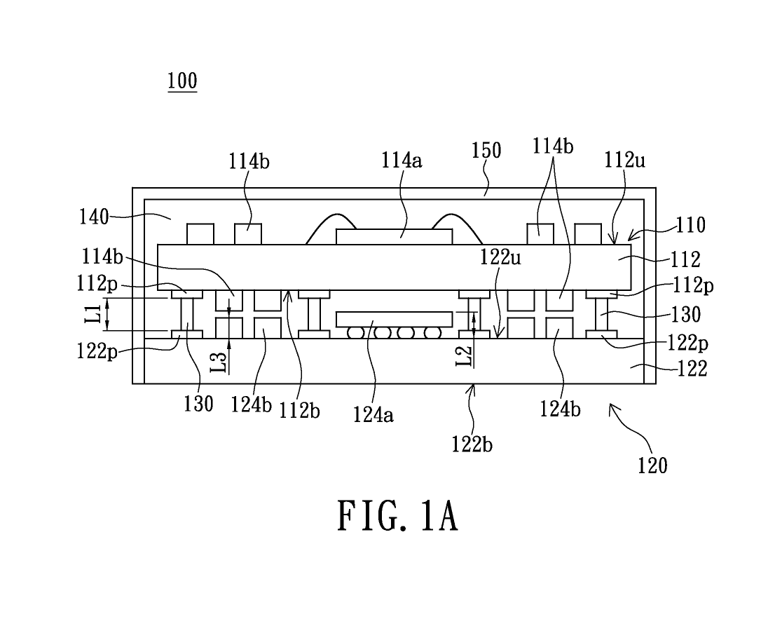

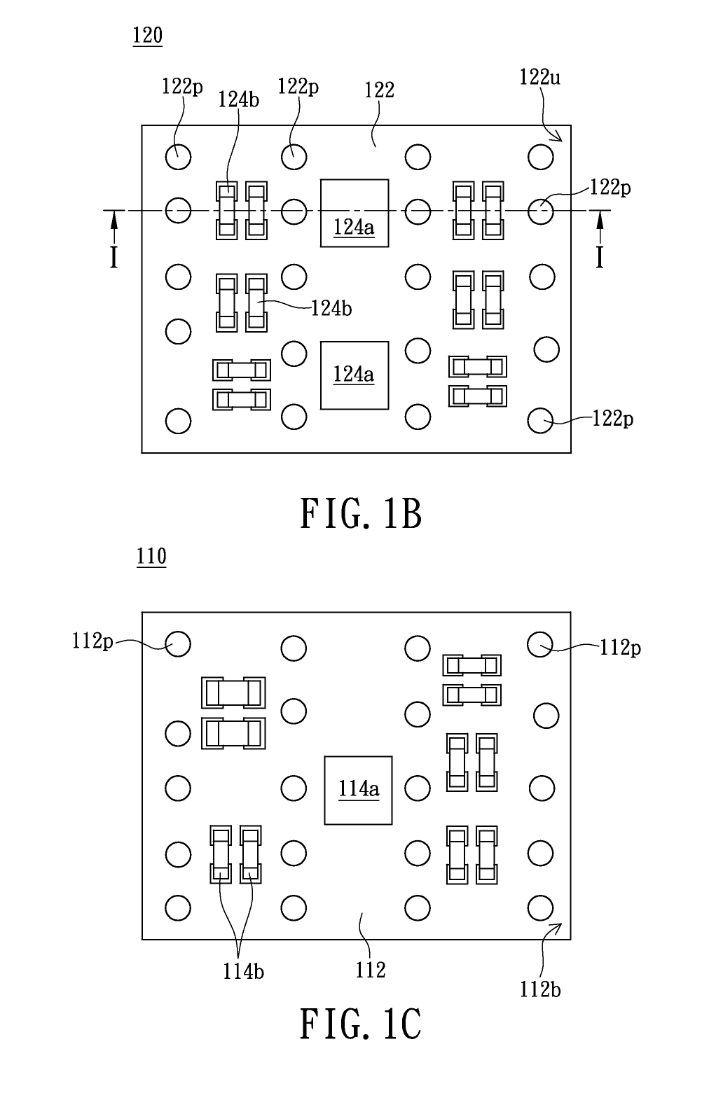

FIG. 1A illustrates a cross-sectional view of a SiP module in accordance with an embodiment of the instant disclosure. Referring to FIG. 1A. The SiP module 100 includes a first circuit board assembly 110, a second circuit board assembly 120 and a plurality of metallic pillars 130. The metallic pillars 130 are arranged between the first circuit board assembly 110 and the second circuit board assembly 120. The metallic pillars 130 electrically connect to both the first circuit board assembly 110 and the second circuit board assembly 120 for electrical signal transmission.

The first and second circuit board assemblies 110, 120 are circuit boards with mounted electronic components. The electronic components can be active or passive components. Active components can be such as chips or transistors, while the passive components can be capacitors, resistors or inductors. Additionally, the chip can be a packaged component or an unpackaged die.

The first circuit board assembly 110 includes a first circuit board unit 112 having a first top surface 112u, a first bottom surface 112b and first electronic components 114a, 114b mounted thereon. The first electronic component 114a may be an active component whereas the first electronic component 114b can be passive component. The first circuit board unit 112 can be a single layer circuit board, a double sided circuit board, or a multilayer circuit board.

The second circuit board assembly 120 is similar to the first circuit board assembly 110. The second circuit board assembly 120 includes a second circuit board unit 122 having a second top surface 122u, a second bottom surface 122b and second electronic components 124a, 124b. The first electronic component 114a is mounted on the first top surface 112u of the first circuit board unit 112 while the first electronic component 114b is mounted on the first bottom surface 112b of the first circuit board unit 112. The second electronic components 124a, 124b are mounted on the second top surface 122u of the second circuit board unit 122. The electronic components can be mounted by wire bonding, flip-chipped or the like.

The second circuit board unit 122 can be mounted on other type of circuit boards, for example, a mother board. The second circuit board unit 122 further has a plurality of soldering pads (not shown) on the second bottom surface 122b. The soldering pads are typically used for soldering the circuit board (e.g. mother board). In other embodiments, the second circuit board unit 122 may not be mounted on other circuit board and therefore the second electronic components 124a, 124b can be mounted on the second bottom surface 122b.

The first circuit board unit 112 may further include a plurality of first pads 112p disposed on the first bottom surface 112b. Likewise, the second circuit board unit 122 may further include a plurality of pads 122p disposed on the second top surface 122u. The metallic pillars 130 are arranged between the first bottom surface 112b of the first circuit board unit 112 and the second top surface 122u of the second circuit board unit 122 and electrically connect the first and second pads 112p, 122p.

The metallic pillars 130 can solder the first and second pads 112p, 122p by solder paste or the like. The metallic pillars 130 are made of metallic materials, for example, copper, aluminum or silver. In addition, the length L1 of the metallic pillars 130 can measure longer than the thickness L2, and the thickness L2 is equivalent to the height of the second electronic component 124a measuring from the second top surface 122u. Besides, the length L1 can also measure longer than the thickness L3, and the thickness L3 is equivalent to the height of the second electronic component 124b measuring from the second top surface 122u.

FIG. 1B illustrates a top schematic view of the second circuit board assembly shown in FIG. 1A. FIG. 1C is a bottom view of the first circuit board assembly shown in FIG. 1A. The line I-I shown in FIG. 1B corresponds to the cross-section of the second circuit board assembly 120 in FIG. 1A. When the first circuit board assembly 110 stacks on the second circuit board assembly 120, the first and second pads 112p, 122p correspond to each other one by one respectively. Thus, the metallic pillars 130 connect each pair of the first and second pads 112p, 122p and form an electrical connection between the first and second circuit board assemblies 110, 120.

The distribution of the first and second pads 112p, 122p shown in FIGS. 1B and 1C may vary according to different arrangement and design of the first and second circuit board assemblies 110, 120. Furthermore, the SiP module 100 may include more than one hundred metallic pillars 130. The arrangement shown in FIGS. 1A to 1C are exemplary embodiments and the instant disclosure is not restricted thereby.

Referring to FIG. 1A again, the SiP module 100 may further include a mold 140. The mold 140 generally fills the space between the first and second circuit board assemblies 110, 120 and encapsulates the metallic pillars 130.

In addition, as shown in FIG. 1A, a shielding layer 150 coats the surface of the mold 140 and the sides of the second circuit board unit 122 to attenuate electromagnetic interference.

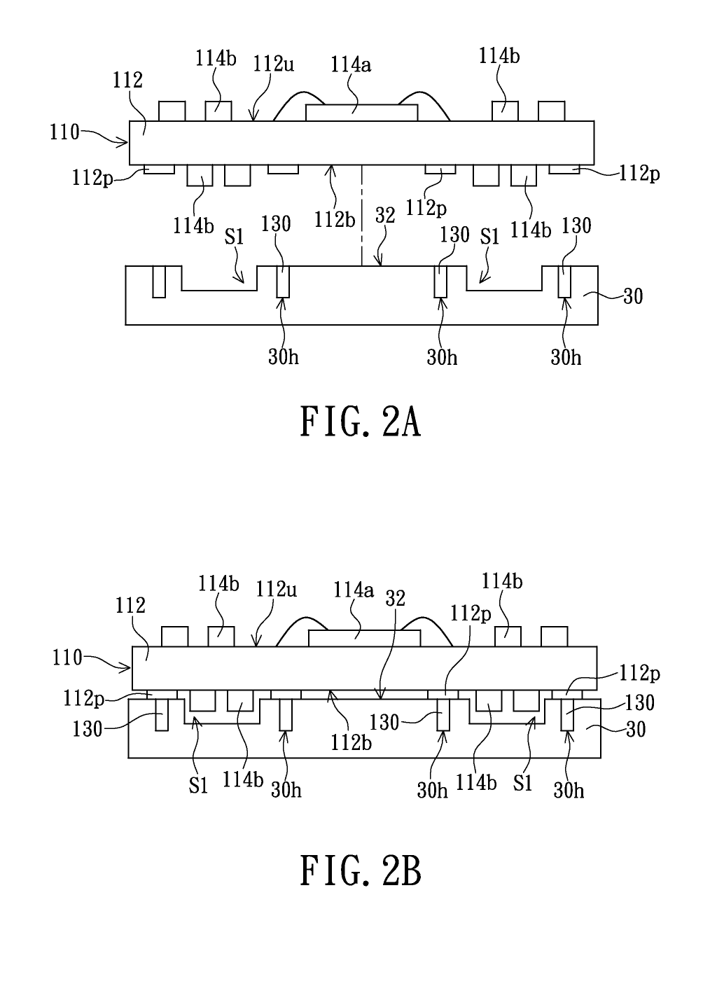

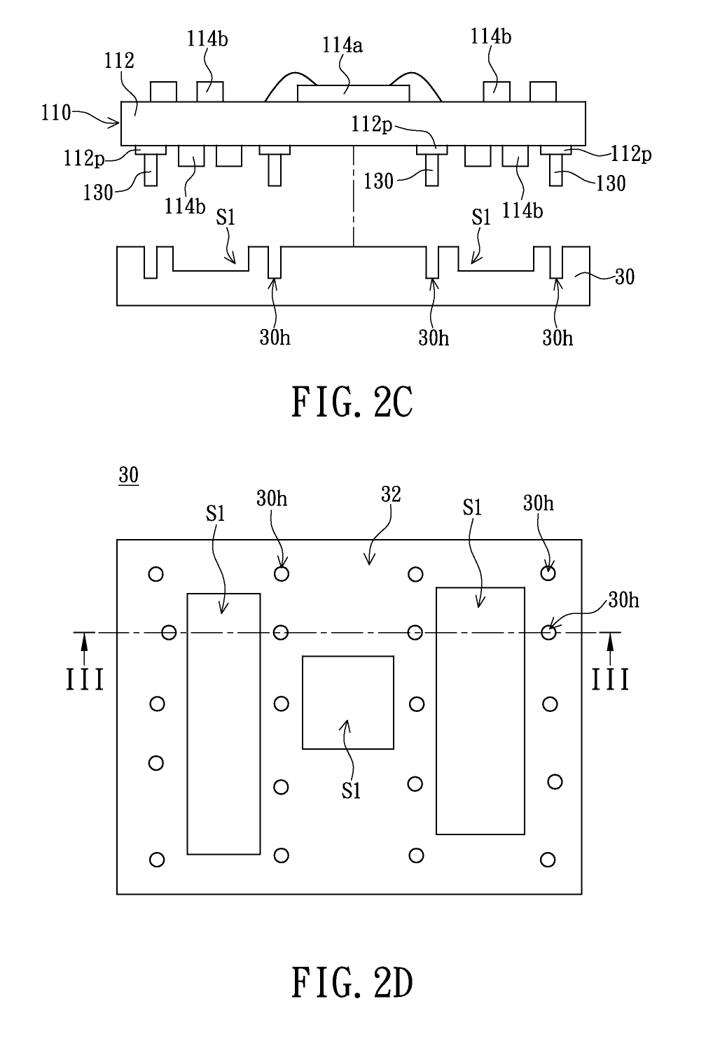

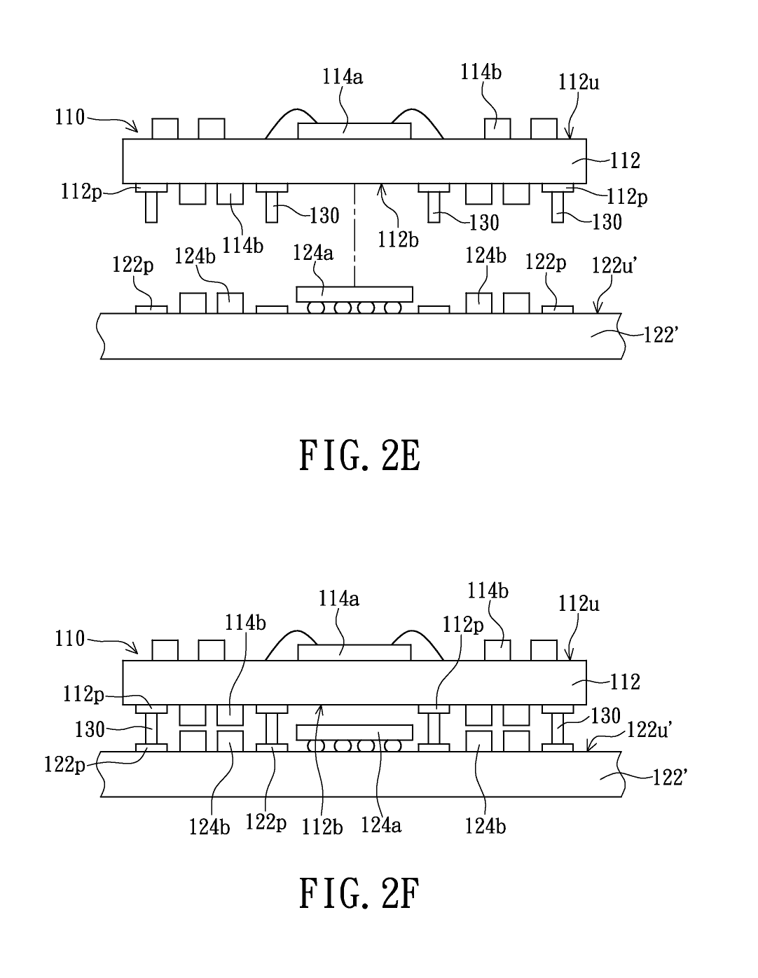

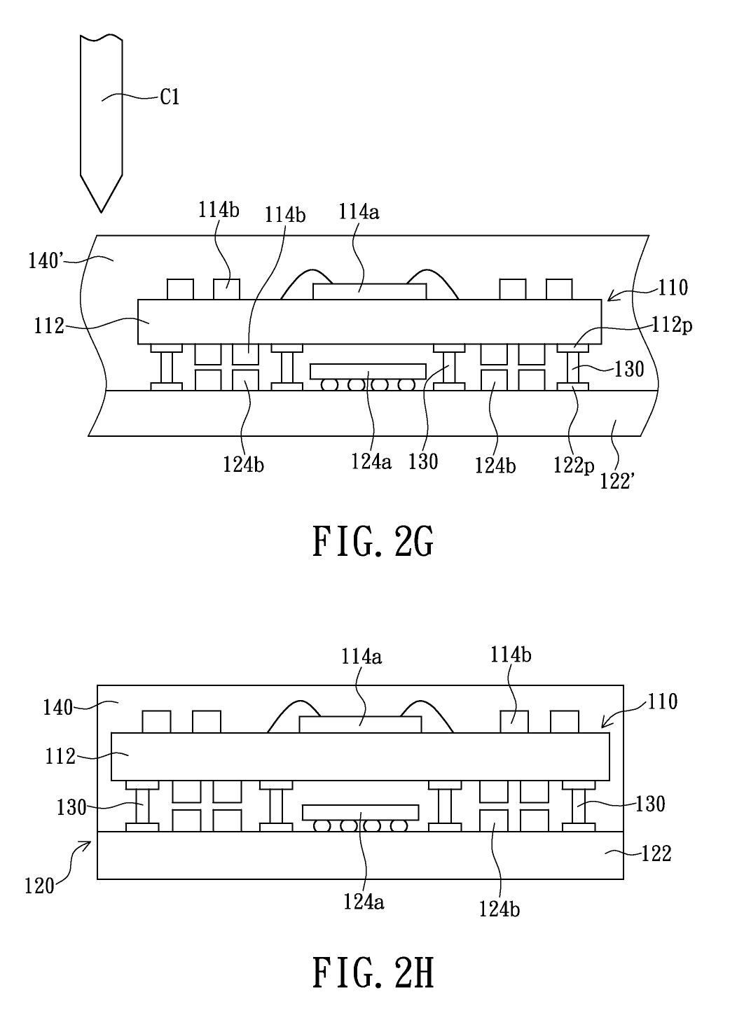

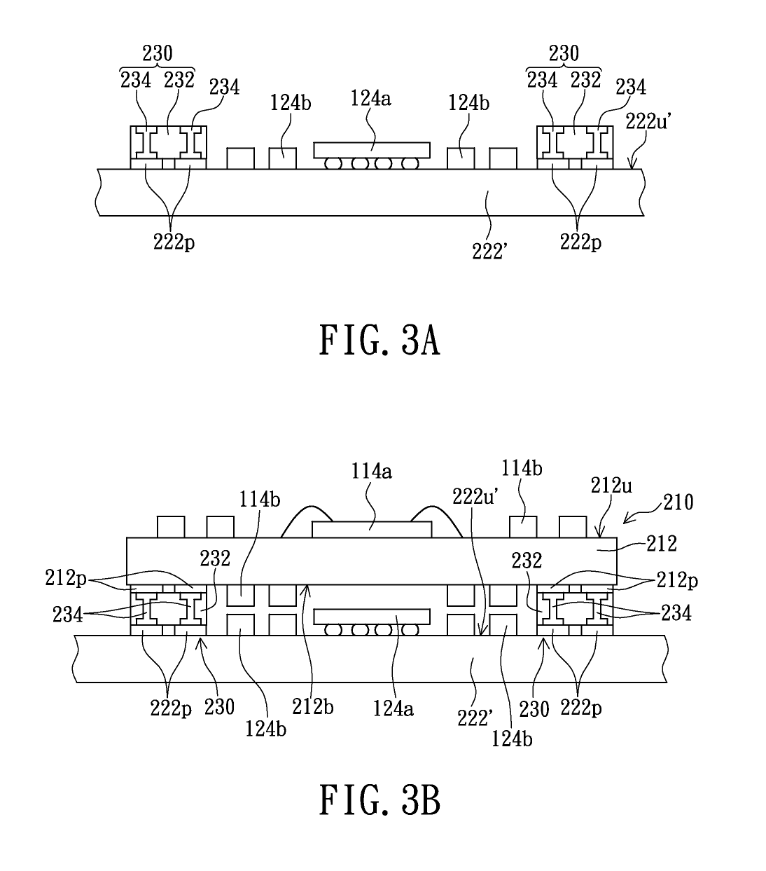

FIGS. 2A to 2H illustrate a method of manufacturing the SiP module shown in FIG. 1A. FIGS. 2A to 2H use a single SiP module 100 for demonstration purpose. However, one ordinary skilled in the art should know that in the instant embodiment the SiP modules 100 can be produced from a circuit panel, which contains the plurality of first circuit board assemblies 110. Alternatively, the plurality of circuit board assemblies 110 undergoes further fabrication with additional tools and therefore the plurality of SiP modules 100 are produced in one line of production.

Referring to FIG. 2A, firstly, the plurality of first circuit board assemblies 110 is provided (only one is shown in FIG. 2A). The first circuit board assemblies 110 may be diced from a large circuit panel or circuit substrate strip.

Referring to FIGS. 2A and 2D, subsequently, a holder 30 is provided, and the metallic pillars 130 are arranged within the holder 30. FIG. 2D illustrates a top view of the holder 30. The holder 30 has a flat face 32, a plurality of holes 30h and a plurality of receiving space S1. The holes 30h and the receiving space S1 are accessible from the flat face 32, and the metallic pillars 130 are disposed within the holes 30h. Then, an adhesive is applied to one side of the metallic pillar 130 or the first pad 112p. The cross-sectional view of the holder 30 shown in FIG. 2A corresponding to the line III-III in FIG. 2D. The receiving space S1 can a recess exposed on the flat face 32 (as shown in FIG. 2A) or an opening by penetrating the holder 30. The distribution of the receiving space S1 corresponds to the arrangement of the electronic components (for example, the first electronic component 114a).

Referring to FIG. 2B. The first circuit board assembly 110 or the holder 30 moves toward the other, and then, the adhesive attaches the metallic pillars 130 and first pads 112p.

Referring to FIG. 2C, the first circuit board assembly 110 or the holder 30 moves apart so the metallic pillars 130 separate from the holder 30. In addition, if soldering materials (such as solder paste) are used to connect the first pads 112p and the metallic pillars 130, after the metallic pillars 130 detach from the holder 30, for example, a reflow process is preformed to heat up the soldering materials. Thus, each metallic pillars 130 respectively solder the first pads 112p.

Referring to FIGS. 2E and 2F, the first circuit board assembly 110 is mounted on the circuit panel 122′. The second circuit board unit 122 shown in FIG. 1A is obtained by dicing the circuit panel 122′ so the circuit panel 122′ has an assembly platform 122u′ and the plurality of pads 122p thereon. Moreover, the first circuit board assembly 110 and second electronic components 124a, 124b can go through the same process or fabricating machine (for example, pick and place machine) for being mounted on the assembly platform 122u′.

Referring to FIGS. 2G and 2H, after mounting the first circuit board assembly 110, a mold material 140′ is formed. The mold material 140′ encapsulates at least the first circuit board assembly 110, metallic pillars 130 and the second electronic components 124a and 124b. Subsequently, as shown in FIG. 2G, a cutter C1 or a laser beam is used to dice the circuit panel 122′ to form individual second circuit board units 122. The mold material 140′ is also cut into the plurality of molds 140 (only one is shown in FIG. 2H).

Referring to FIGS. 2H and 1A, then the shielding layer 150 is formed to cover the mold 140 (only one is shown in FIG. 1A). So far, the process of manufacturing SiP module 100 is generally completed. The formation of the shielding layer 150 can be achieved by Physical Vapor Deposition (PVD) or spray coating. The PVD can be evaporation or sputtering.

In other applications, after the first circuit board assembly 110 is mounted on the circuit panel 122′ (as shown in FIG. 2F), the circuit panel 122′ is diced to the plurality of second circuit board units 122. The steps of forming the mold material 140′ and shielding layer 150 may be skipped. If the SiP module 100 needs electromagnetic interference shielding, a metal lid can be used to replaced the metal layer 150 and serve the same function. The metal lid may covering the first circuit board assembly and being fastened on the second top surface.

Based on the preceding manufacturing method, the metallic pillars 130 are connected to the first circuit board assembly 110 at first and then mounted on the circuit panel 122′. Alternatively, the metallic pillars 130 can be connected to the circuit panel 122′ and then the first circuit board assembly 10 is mounted on the circuit panel 122′.

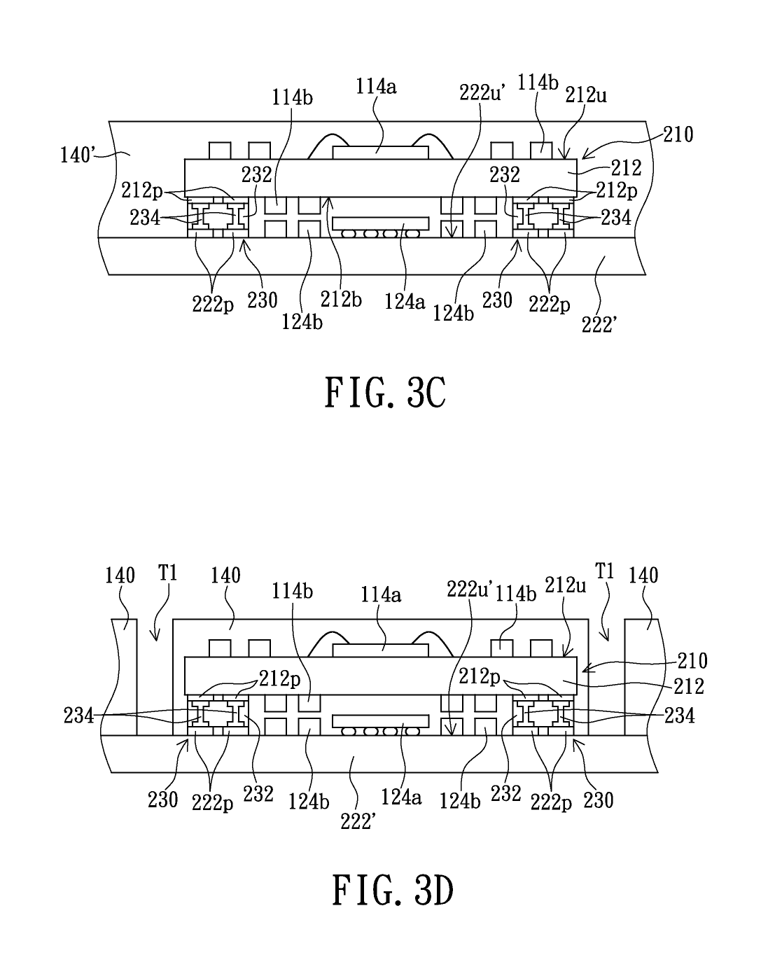

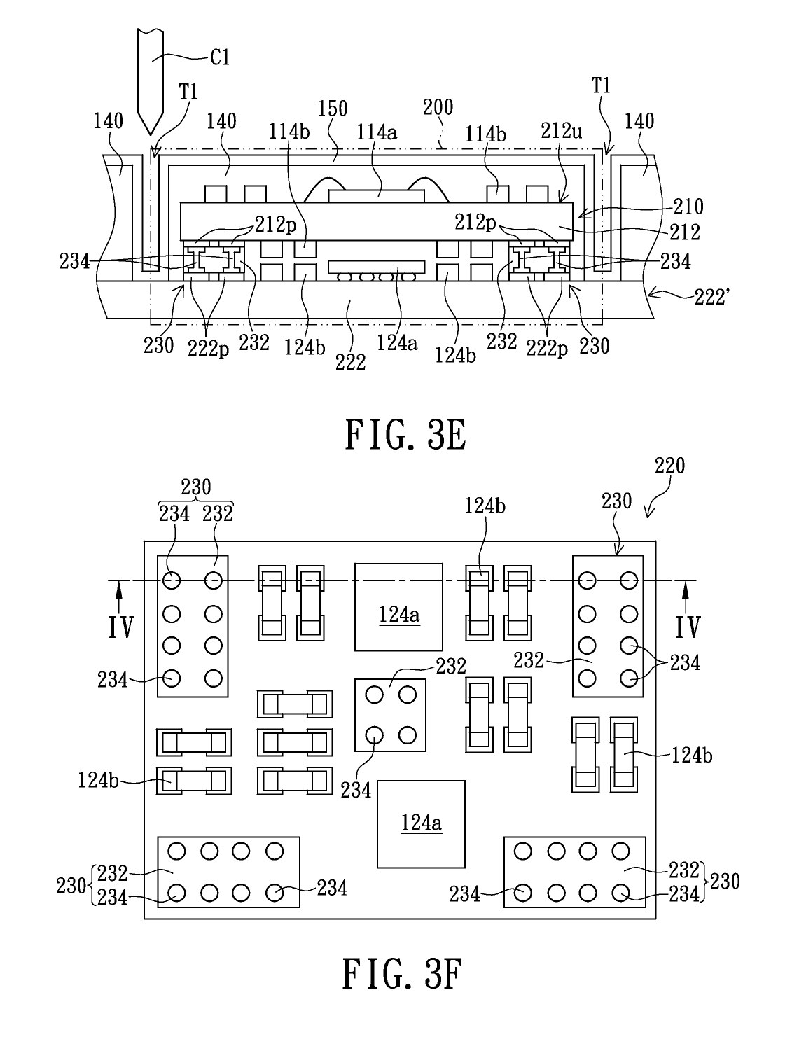

FIGS. 3A to 3F illustrate schematic views of the method of manufacturing the SiP module in accordance with another embodiment of the instant disclosure. The method as shown in FIG. 3A to 3F is similar to aforementioned embodiment. The difference between the aforementioned and instant methods arises from that the metallic pillars are replaced by the micro circuit boards. The micro circuit board has at least one function of the metallic pillar. Referring to FIG. 3A, firstly, the plurality of micro circuit boards 230 and second electronic components 124a, 124b are mounted on the circuit panel 222′ by pick and place machine. The second pads 222p may be disposed on the assembly platform 222u′ or embedded in the circuit panel 222′.

Each micro circuit board 230 contains at least one metallic pillar 234 (more than one is shown in FIG. 3A) and an insulating piece 232, in which the metallic pillars 234 are integrated with an insulating piece 232 which surrounds the metallic pillars 234. The micro circuit board 230 can be made from dicing existing circuit board.

Referring to FIG. 3B, subsequently, the plurality of first circuit board assemblies 210 (only one is shown in FIG. 3B) is attached on the micro circuit boards 230. The metallic pillars 234 of the micro circuit boards 230 electrically connect the corresponding pads between the first circuit board assembly 210 and circuit panel 222′.

Referring to FIG. 3C, then the mold material 140′ is formed to coat the first circuit board assembly 210, micro circuit boards 230 and second electronic components 124a, 124b.

Referring to FIG. 3D, the cutter or the laser beam is used to cut the mold material 140′ yet not through the circuit panel 222′ to form a plurality of trenches T1 exposing the part of the assembly platform 222u′.

Referring to FIG. 3E, the shielding layer 150 is formed to cover the mold 140. Then, the cutter C1 or the laser beam is used to dice the circuit panel 222′ to form individual SiP module 200 (as the dotted-line area shown in FIG. 3E).

The SiP module 100 which includes the metallic pillars 130 can also be produced by the aforementioned method. The first circuit board assembly 210, second circuit board assembly 220, circuit panel 222′ and micro circuit boards 230 can be replaced respectively by the first circuit board assembly 110, second circuit board assembly 120, circuit panel 122′ and metallic pillars 130.

Furthermore, SiP modules 100 or 200 may include micro circuit boards 230 and metallic pillars 130.

FIG. 3F is a top view of the second circuit board and micro circuit board shown in FIG. 3E. The line Iv-Iv in FIG. 3F corresponds to the cross-section in FIG. 3E. Referring to FIGS. 3E and 3F, the micro circuit boards 230 can support the first circuit board assembly 210, and four micro circuit boards 230 can be positioned at the four corners of the second circuit board assembly 220.

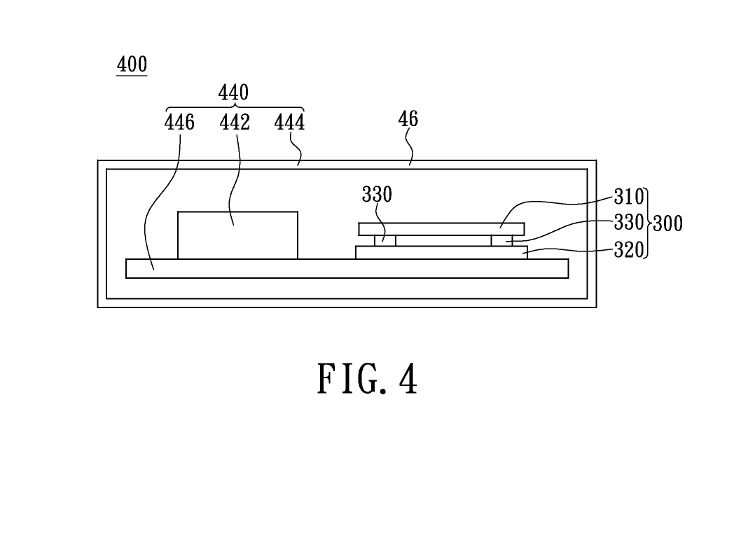

FIG. 4 illustrates a schematic view of an electronic device using the SiP in accordance with an embodiment of the instant disclosure. The electronic device 400 can be a mobile device, a desktop computer or a computer peripheral. The mobile device can be such as a cell phone, a tablet or a laptop. The computer peripheral can be a Bluetooth device, a wireless station or a router.

The electronic device 400 includes the SiP module 300 and a main body 440. The SiP module 300 electrically connects the main body 440. Specifically, the SiP module 300 can be a data storage device, an image processor or a wireless module of the electronic device 400. The SiP module 300 includes the first circuit board assembly 310, second circuit board assembly 320 and a plurality of connectors 330.

The first circuit board assembly 310 is equivalent to the first circuit board assembly 110 or 210 in the aforementioned embodiments. The second circuit board assembly 320 is equivalent to the second circuit board assembly 120 or 220 in the aforementioned embodiments. The connectors 330 are the metallic pillars 130 or micro circuit boards 230 previously mentioned. The SiP module 300 can be the SiP module 100 or 200 previously mentioned.

The main body 440 is a component other than SiP module 300 and includes at least one electronic module 442, a chassis 444 and a circuit board 446. The electronic module 442 and the SiP module 300 are mounted on the circuit board 446. The electronic module 442, the SiP module 300, and the circuit board 446 are disposed within the chassis 444. In practical, the circuit board 446 can be a mother board, and the electronic module 442 can be control processor, for example, central processing unit (CPU). The electronic module 442 can electrically connect to the SiP module 300 through the circuit board 446. Thus the electronic module 442 can control the operation of the SiP module 300. In other applications, the SiP module 300 can be the control processor (such as CPU) while the electronic module 442 can be the data storage device, image processor or wireless module. The electronic module 442 can be in operation via the control of the SiP module 300. In addition, the electronic module 442 may be a SiP module 300 so the electronic device 400 may contain one, two, or more than two SiP modules 300.

Therefore, the metallic pillars and/or the metallic pillars within the micro circuit board electrically connect the first and second circuit board assemblies. Thus, the aforementioned metallic pillars can reduce the entire thickness and volume of the SiP module.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A system in package module comprising:
a first circuit board assembly comprising a first circuit board unit and at least one first electronic component mounted thereon, the first circuit board unit having a first top surface, a first bottom surface and a plurality of first pads disposed on the first bottom surface;
a second circuit board assembly comprising a second circuit board unit and at least one second electronic component mounted thereon, the second circuit board unit having a second top surface, a second bottom surface and a plurality of second pads disposed on the second top surface; and
at least one conductive pillar arranged between the first bottom surface and second top surface, wherein the conductive pillar is electrically connected to the corresponding first and second pads.

2. The system in package module according to claim 1 further comprising a mold encapsulating the first circuit board assembly, the second circuit board assembly, and the conductive pillar.

3. The system in package module according to claim 2 further comprising a shielding layer coating the mold.

4. The system in package module according to claim 1 further comprising a metal lid covering the first circuit board assembly and being fastened on the second top surface.

5. The system in package module according to claim 1, wherein the conductive pillar is a metallic pillar or a micro circuit board that is formed by an insulating material surrounding at least one metallic pillar.

6. A method of manufacturing system in package module comprising:
providing at least one first circuit board assembly, the first circuit board assembly comprising a first circuit board unit, at least one first electronic component and at least one first pad;
providing a circuit panel comprising at least one second electronic component and at least one second pad;
providing at least one conductive pillar;
arranging the conductive pillar between the first pad and the second pad according to the need of an electrical connection between the first circuit board assembly and the circuit panel; and
dicing the circuit panel to form at least one system in package module.

7. The method of manufacturing system in package module according to claim 6, wherein the conductive pillar is a metallic pillar.

8. The method of manufacturing system in package module according to claim 7, wherein the step of arranging the conductive pillar between the first pad and the second pad further comprising:
providing a holder with at least one hole to receive the metallic pillar;
applying an adhesive on one side of the metallic pillar, the first pad or the second pad;
moving the holder for connecting the first pad or the second pad via the metallic pillar; and
detaching the metallic pillar from the holder.

9. The method of manufacturing system in package module according to claim 6, wherein the conductive pillar is a micro circuit board formed by an insulating material surrounding at least one metallic pillar, and the micro circuit board and the second electronic component attach to the circuit panel by surface-mount technology.

10. An electronic device comprising:
a main body comprising at least one electronic module, a chassis and a circuit board; and
at least one system in package module according to claim 1;
wherein the second circuit board assembly electrically connects to the circuit board.

11. The electronic device according to claim 10, wherein the system in package module is made by a method comprising:
providing at least one first circuit board assembly, the first board assembly comprising a first circuit board unit, at least one first electronic component and at least one first pad;
providing a circuit panel comprising at least one second electronic component and at least one second pad;
providing at least one conductive pillar;
arranging the conductive pillar between the first pad and the second pad according to the need of an electrical connection between the first circuit board assembly and the circuit panel; and
dicing the circuit panel to form at least one system in package module.

12. The electronic device according to claim 11, wherein the conductive pillar is a metallic pillar.

13. The electronic device according to claim 12, wherein the step of arranging the conductive pillar between the first pad and the second pad further comprising:
providing a holder with at least one hole to receive the metallic pillar;
applying an adhesive on one side of the metallic pillar, the first pad or the second pad;
moving the holder for connecting the first pad or the second pad via the metallic pillar; and
detaching the metallic pillar from the holder.

14. The electronic device according to claim 11, wherein the conductive pillar is a micro circuit board formed by an insulating material surrounding at least one metallic pillar, and the micro circuit board and the second electronic component attach to the circuit panel by surface-mount technology.
